(19) United States
(12) Patent Application Publication
(10) Pub. No.: US 2026/0171998 A1
(43) Pub. Date: Jun. 18, 2026

(54) BULK ACOUSTIC WAVE RESONATOR DEVICE WITH IMPROVED QUALITY FACTOR AND RELATED MANUFACTURING PROCESS

(71) Applicant: STMicroelectronics International N.V., Geneva (CH)

(72) Inventors: Domenico GIUSTI, Caponago (IT); Carla Maria LAZZARI, Lesmo (MB) (IT); Andreja ERBES, Antibes (FR)

(73) Assignee: STMicroelectronics Internation N.V., Geneva (CH)

(21) Appl. No.: 19/422,070

(22) Filed: Dec. 16, 2025

(30) Foreign Application Priority Data
Dec. 18, 2024 (IT) 102024000028848

(51) Int. Cl. H03H 9/02; H03H 3/02; H03H 9/13

(52) U.S. Cl. CPC H03H 9/02007; H03H 3/02; H03H 9/13; H03H 2003/025

(57) ABSTRACT

A bulk acoustic wave resonator device includes a piezoelectric resonator having a top electrode, a bottom electrode and a piezoelectric region interposed between the top electrode and the bottom electrode. A central acoustic mirror of the Bragg type is arranged under the piezoelectric resonator and includes respective layers extending parallel to a reference plane. One or more peripheral acoustic mirrors of the Bragg type are arranged laterally with respect to the central acoustic mirror. Each peripheral acoustic mirror includes a respective sequence of alternating high acoustic impedance regions and low acoustic impedance regions. Each of the high acoustic impedance regions and low acoustic impedance regions extends transversally with respect to the reference plane.

### PRIORITY CLAIM

This application claims the priority benefit of Italian Application for Patent No. 102024000028848 filed on Dec. 18, 2024, the content of which is hereby incorporated by reference in its entirety to the maximum extent allowable by law.

### TECHNICAL FIELD

The present invention relates to a bulk acoustic wave (BAW) resonator device with an improved quality factor and the related manufacturing process.

### BACKGROUND

As is known, radio-frequency (RF) resonator devices based on micro-acoustic technologies and thin-film technologies are widely used to form, as an example, radio frequency (RF) filters, which are commonly used in the mobile phones, wireless networks, etc. These filters are characterized by small size and high mass-producibility.

In greater detail, among the RF resonator devices there exist semiconductive resonator devices based on the so-called bulk acoustic wave (BAW) technology. Furthermore, among the BAW resonator devices, there exist the so-called solidly-mounted resonators (SMR), namely BAW resonator devices wherein the piezoelectric region is formed on top of a body without any cavity. An example of a solidly-mounted BAW resonator device is shown in FIG. 1.

In particular, FIG. 1 shows a resonator device 1, which includes a semiconductive substrate 2, which is overlaid by an acoustic mirror 5 of the Bragg type, which is formed by a stack of alternating high acoustic impedance layers (designated by 6 and formed, as an example, by tungsten or molybdenum) and low acoustic impedance layers (designated by 8 and formed, as an example, by silicon oxide). An intermediate layer 9 made of aluminum nitride (AlN) may be arranged on the acoustic mirror 5. Furthermore, the resonator device 1 comprises a piezoelectric resonator 10, which is arranged on top of the intermediate layer 9 and includes: a bottom electrode 11, which is arranged on the intermediate layer 9; a piezoelectric layer 12, which is arranged on the bottom electrode 11; and a top electrode 13, which is arranged on the piezoelectric layer 12.

In use, an input signal is present on the top electrode 13, whereas an output signal is present on the bottom electrode 11. Furthermore, by electrically connecting several devices like the resonator device 1, as an example so as to form a ladder circuit, it is possible to form an electric filter.

In detail, the voltages of the input signal and the output signal cause the generation of acoustic waves that propagate in the piezoelectric layer 12; ideally, the acoustic waves interfere so as to form a standing wave in the piezoelectric layer 12, in the vertical direction.

The acoustic mirror 5 serves to confine the acoustic waves within the piezoelectric layer 12, in the vertical direction, so as to reduce their propagation into the semiconductive substrate 2. However, different types of vibrations (i.e., acoustic waves) can propagate in the piezoelectric layer 12 also in a horizontal direction (i.e., in a direction parallel to the piezoelectric layer 12).

Examples of vibration types that can propagate in the piezoelectric layer 12 include the thickness-extensional (TE) vibrations (in particular, bulk waves), in which the particle displacement is in the thickness direction of the piezoelectric layer 12, and the thickness-shear (TS) vibrations, in which the particle displacement is in a direction perpendicular to the thickness direction of the piezoelectric layer 12. To achieve a high quality factor (Q), it is necessary to implement either a vertical confinement and a lateral confinement of the acoustic waves, in particular at the resonance frequency of the resonator device 1 and in a frequency band around the resonance frequency.

Unfortunately, though the resonator device 1 exhibits a quality factor that may be sufficient for certain applications, in general the need is felt of improving the quality factor of the known BAW resonator devices.

There is a need in the art to provide a BAW resonator device with an improved quality factor.

### SUMMARY

In an embodiment, a bulk acoustic wave resonator device comprises: a piezoelectric resonator comprising a top electrode, a bottom electrode and a piezoelectric region interposed between the top electrode and the bottom electrode; a central acoustic mirror of the Bragg type, arranged under the piezoelectric resonator and including respective layers extending parallel to a reference plane; and one or more peripheral acoustic mirrors of the Bragg type, arranged laterally with respect to the central acoustic mirror. Each peripheral acoustic mirror comprises a respective sequence of alternating high acoustic impedance regions and low acoustic impedance regions, each of said high acoustic impedance regions and low acoustic impedance regions extending transversally with respect to the reference plane.

In an embodiment, a process for manufacturing a bulk acoustic wave resonator device comprises: forming a piezoelectric resonator including a top electrode, a bottom electrode and a piezoelectric region interposed between the top electrode and the bottom electrode; forming a central acoustic mirror of the Bragg type, arranged under the piezoelectric resonator and including respective layers extending parallel to a reference plane; and forming one or more peripheral acoustic mirrors of the Bragg type, arranged laterally with respect to the central acoustic mirror. Each peripheral acoustic mirror comprises a respective sequence of alternating high acoustic impedance regions and low acoustic impedance regions, each of said high acoustic impedance regions and low acoustic impedance regions extending transversally with respect to the reference plane.

### BRIEF DESCRIPTION OF THE DRAWINGS

For a better understanding of the present invention, embodiments thereof are now described, purely by way of non-limiting example, with reference to the attached drawings, wherein:

FIG. 1 schematically shows a cross-section of a resonator device;

FIG. 2 schematically shows a top plan view of a resonator device with removed portions;

FIG. 3 schematically shows a cross-section of a portion of the resonator device shown in FIG. 2, taken along a cross-section line III-III shown in FIG. 2;

FIGS. 4-12 schematically show cross-sections of a portion of the resonator device shown in FIGS. 2 and 3, during subsequent steps of a manufacturing process; and

FIG. 13 schematically shows a cross-section of a portion of a variant of the resonator device shown in FIGS. 2 and 3; and

FIGS. 14-16 schematically show cross-sections of a portion of the resonator device shown in FIG. 13, during subsequent steps of a manufacturing process.

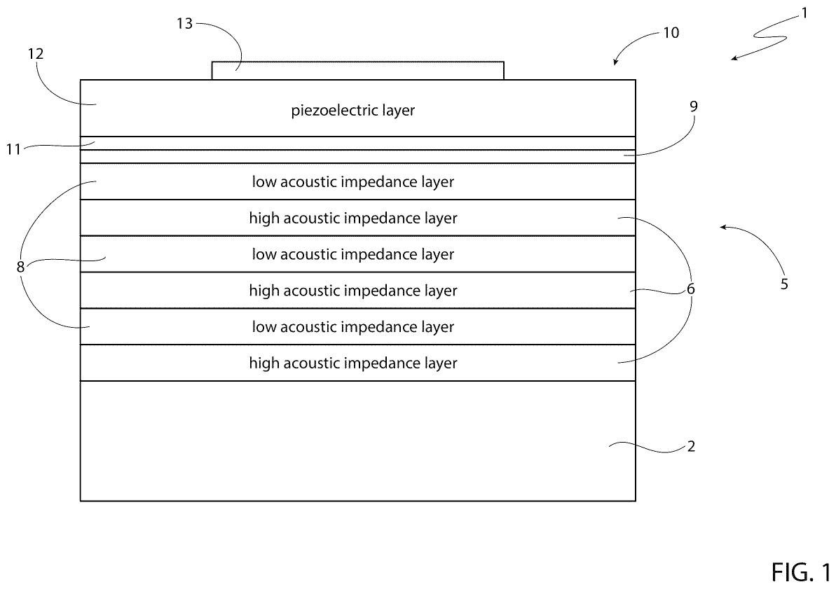

### DETAILED DESCRIPTION

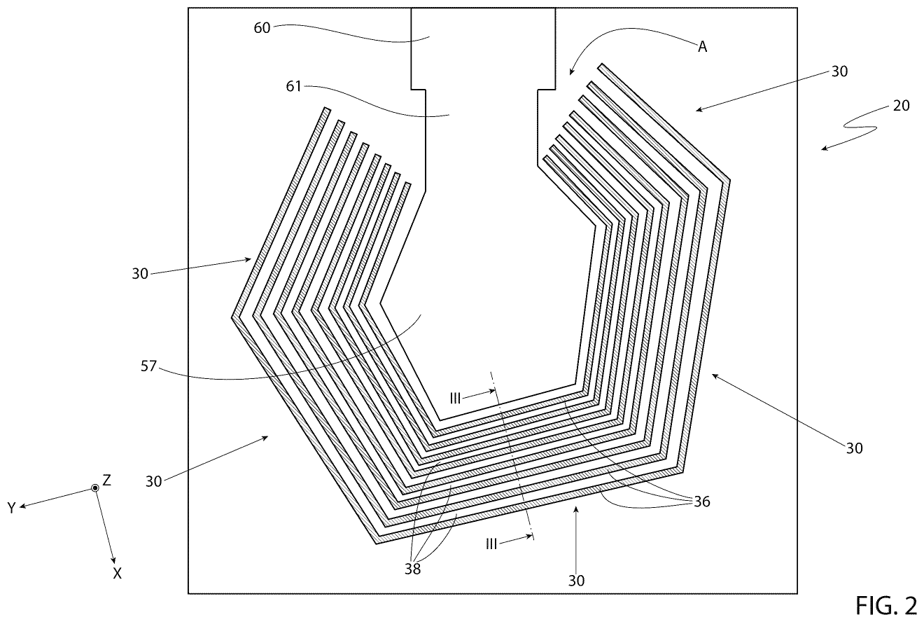

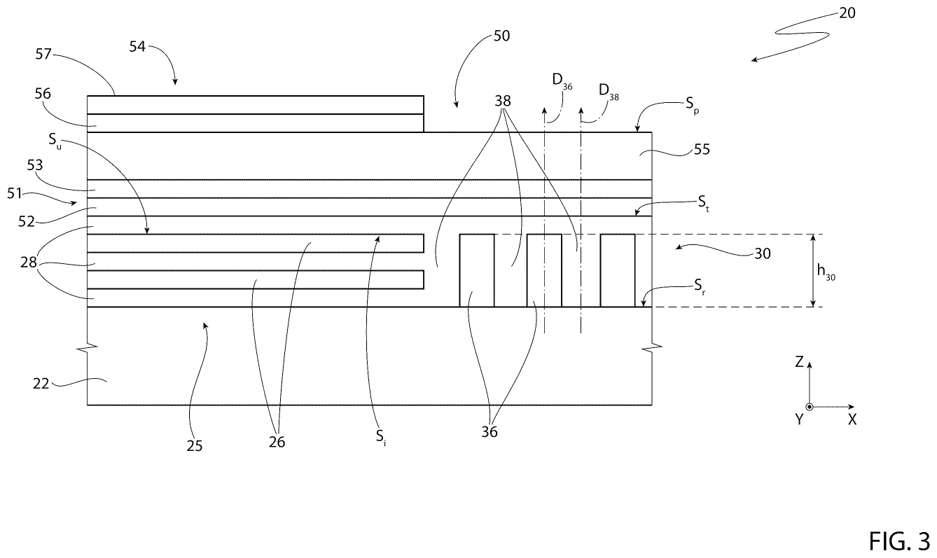

FIGS. 2 and 3 show a solidly-mounted BAW resonator device 20, hereinafter referred to as the resonator device 20, and an orthogonal reference system XYZ.

The resonator device 20 includes a semiconductive substrate 22, which is delimited at top by a reference surface Sᵣ, which is parallel to the plane XY. As an example, the semiconductive substrate 22 may be made of silicon.

A central portion of the semiconductive substrate 22 is overlaid by a central acoustic mirror 25 of the Bragg type, which is formed by a sequence of alternating high acoustic impedance layers (designated by 26 and formed, as an example, by tungsten or molybdenum) and low acoustic impedance layers (designated by 28 and formed, as an example, by silicon oxide), vertically stacked.

For the sake of simplicity, in the example shown in FIGS. 2 and 3 the central acoustic mirror 25 includes only three low acoustic impedance layers 28 and two high acoustic impedance layers 26, which approximately have planar shapes and extend parallel to the plane XY. Furthermore, without any loss of generality, a first high acoustic impedance layer 28 is arranged on the central portion of the semiconductive substrate 22, in direct contact; a second low acoustic impedance layer 28 is interposed between the pair of the high acoustic impedance layers 26; and a third low acoustic impedance layer 28 is arranged on the topmost high acoustic impedance layer 26. The third low acoustic impedance layer 28 is delimited at top by a top surface Sₜ, which is parallel to the plane XY and delimits the central acoustic mirror 25.

The resonator device 20 further includes five peripheral acoustic mirrors 30 of the Bragg type, which are arranged on a peripheral portion of the semiconductive substrate 22, so as to partially surround the central acoustic mirror 25, laterally.

As visible in FIG. 3, each peripheral acoustic mirror 30 comprises a respective sequence of alternating high acoustic impedance regions (designated by 36 and formed, as an example, by tungsten or molybdenum) and low acoustic impedance regions (designated by 38 and formed, as an example, by silicon oxide).

In particular, each of the high acoustic impedance regions 36 and the low acoustic impedance regions 38 approximately has the shape of a parallelepiped that has a symmetry axis parallel to the axis Z. Furthermore, each sequence of alternating high acoustic impedance regions 36 and low acoustic impedance regions 38 extends in a corresponding sequence direction, which is substantially parallel to the plane XY, and the respective high acoustic impedance regions 36 and low acoustic impedance regions 38 have planar shapes that extend perpendicularly with respect to the sequence direction. As an example, FIG. 3 shows a portion of the peripheral acoustic mirror 30 whose sequence direction is parallel to the axis X. Furthermore, the width (parallel to the sequence direction) of the high acoustic impedance regions 36 of a peripheral acoustic mirror 30 may vary along the corresponding sequence direction (i.e., it may be not constant). Similarly, the width of the low acoustic impedance regions 38 of a peripheral acoustic mirror 30 may vary along the corresponding sequence direction. As a consequence, though not shown, the spacing of the high acoustic impedance regions 36 and the low acoustic impedance regions 38 of a peripheral acoustic mirror 30 may vary along the corresponding sequence direction.

In greater detail, each of the high acoustic impedance regions 36 has a shape that extends vertically with a height h₃₀ (measured parallel to the axis Z), with a lower end arranged on the reference surface Sᵣ. Without any loss of generality, the height h₃₀ is such that the upper end of each of the high acoustic impedance regions 36 is coplanar with the upper surface (designated by Sᵤ in FIG. 3) of the topmost high acoustic impedance layer 26 of the central acoustic mirror 25.

In practice, the high acoustic impedance regions 36 and the low acoustic impedance regions 38 have shapes elongated in respective directions (designated respectively by D₃₆ and D₃₈ in FIG. 3), which are parallel to the axis Z.

In addition, the topmost low acoustic impedance layer 28 of the central acoustic mirror 25 extend laterally so as to overlie, in direct contact, the upper ends of the high acoustic impedance regions 36 and the low acoustic impedance regions 38 of the peripheral acoustic mirrors 30, forming a single structure made of silicon oxide with the low acoustic impedance regions 38. In addition, still without any loss of generality, the innermost low acoustic impedance region 38 of each peripheral acoustic mirror 30 laterally contacts the high acoustic impedance layers 26 and the low acoustic impedance layers 28 of the central acoustic mirror 25. Therefore, also the low acoustic impedance layers 28 of the central acoustic mirror 25 form the abovementioned structure made of silicon oxide.

Furthermore, as visible in FIG. 2, and without any loss of generality, the peripheral acoustic mirrors 30 comprise the same number of high acoustic impedance regions 36 and the same number of low acoustic impedance regions 38. In addition, in top view the peripheral acoustic mirrors 30 are arranged approximately according to an incomplete polygonal shape; each pair of adjacent peripheral acoustic mirrors 30 are such that, considering each high acoustic impedance region 36 of a first mirror of the pair, it laterally contacts a corresponding high acoustic impedance region 36 of a second mirror of the pair, and, similarly, considering each low acoustic impedance region 38 of the first mirror of the pair, it laterally contacts a corresponding low acoustic impedance region 38 of the second mirror of the pair.

The resonator device 20 further comprises a piezoelectric resonator 50, which is arranged on the top surface Sₜ and includes a bottom electrode 51, a piezoelectric region 55 and a top electrode 54, the piezoelectric region 55 being interposed between the bottom electrode 51 and the top electrode 54.

In particular, the bottom electrode 51 may comprise: a first bottom conductive region 52, which is arranged on the top surface Sₜ and is made, as an example, made of molybdenum; and a second bottom conductive region 53, which is arranged on the first bottom conductive region 52 and is made, as an example, made of platinum. The piezoelectric region 55 is arranged on the second bottom conductive region 53.

The top electrode 54 may comprise: a first top conductive region 56, which is arranged on the piezoelectric region 55 and is made, as an example, made of molybdenum; and a second top conductive region 57, which is arranged on the first top conductive region 56 and is made, as an example, made of aluminum.

In greater detail, the piezoelectric region 55 is delimited at top by a surface Sₚ, hereinafter referred to as the piezoelectric surface Sₚ. Furthermore, in top view the first and second top conductive regions 56, 57 may have the same planar shape and overlie, at distance, the central acoustic mirror 25; in addition, the first and second top conductive regions 56, 57 leave exposed portions of the piezoelectric surface Sₚ that overlie, at distance, the peripheral acoustic mirrors 30. Furthermore, as visible in FIG. 2, the first and second top conductive regions 56, 57 may have a non-symmetric planar shape, so as to avoid the generation of acoustic standing waves in directions parallel to the plane XY, in the piezoelectric region 55.

The first and second bottom conductive regions 52, 53 may have the same planar shape and extend laterally so as to overlie either the central acoustic mirror 25 and the peripheral acoustic mirrors 30. To this regard, in FIG. 2 the piezoelectric region 55, the first and second bottom conductive regions 52, 53 and the third low acoustic impedance layer 28 have been removed to show the arrangement of regions 36, 38.

In practice, the bottom electrode 51 overlies the central acoustic mirror 25 and the peripheral acoustic mirrors 30. The top electrode 54 overlies, at distance, the central acoustic mirror 25; the peripheral acoustic mirrors 30 are laterally staggered with respect to the top electrode 54.

In addition, though not shown, a portion of the second bottom conductive region 53 may be made accessible for electrical routing by exposing this portion through a hole extending through an exposed portion of the piezoelectric region 55.

In greater detail, as visible in FIG. 2, the peripheral acoustic mirrors 30 are arranged according to an incomplete polygonal shape that defines an access region A made of silicon oxide. Furthermore, the resonator device 20 comprises, in a per se known manner, a conductive pad 60 and a conductive path 61, which extends on the access region A and connects the conductive pad 60 to the top electrode 54. Though not shown in detail, the conductive pad 60, the conductive path 61 and the top electrode 54 are coplanar; furthermore, in use the conductive pad 60 receives an input signal, which is then applied to the top electrode 54. The output signal is present on the bottom electrode 51.

In use, the peripheral acoustic mirrors 30 allow to support evanescent waves (along directions parallel to the plane XY) only, in the space portions surrounding the piezoelectric resonator 50, thereby improving the lateral confinement of the acoustic energy in the piezoelectric region 55 at the resonance frequency and in a corresponding band including the resonance frequency.

The resonator device 20 may be formed by the manufacturing process described hereinafter, starting from the semiconductive substrate 22.

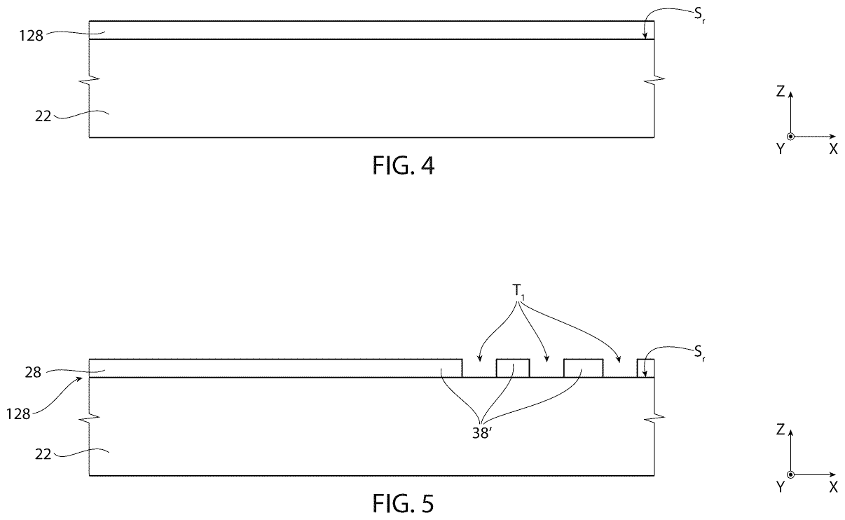

Initially, as shown in FIG. 4, a first dielectric layer 128 made of silicon oxide is formed on the reference surface Sᵣ. Then, as shown in FIG. 5, portions of the first dielectric layer 128 are selectively removed, e.g., through a dry etching, so to form a temporary trench T₁ for each of the high acoustic impedance regions 36. In practice, the temporary trenches T₁ (hereinafter referred to as the first temporary trenches T₁) extend through the first dielectric layer 128 and are delimited at their bottoms by the semiconductive substrate 22. Furthermore, the remaining portions of the first dielectric layer 128 form the bottommost low acoustic impedance layer 28 of the central acoustic mirror 25 and corresponding first portions 38′ of the low acoustic impedance regions 38. Each first temporary trench T₁ is delimited laterally by a corresponding pair of first portions 38′ of the low acoustic impedance regions 38.

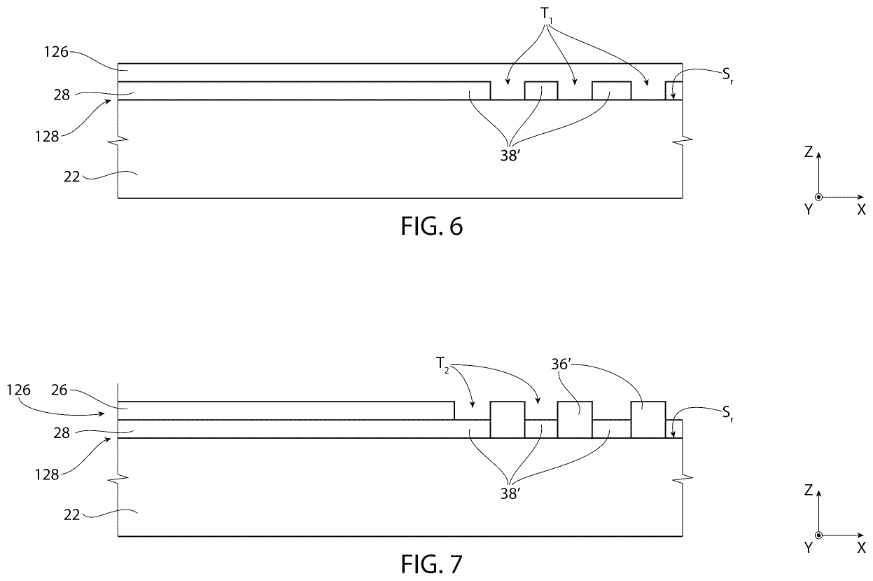

Afterwards, as shown in FIG. 6, a first conductive layer 126 (e.g., made of tungsten or molybdenum) is formed on the first dielectric layer 128, namely on the bottommost low acoustic impedance layer 28 of the central acoustic mirror 25, on the abovementioned first portions 38′ of the low acoustic impedance regions 38 and inside the first temporary trenches T₁, so as to fill the first temporary trenches T₁.

Subsequently, as shown in FIG. 7, a dry etching is carried out, in order to selectively remove portions of the first conductive layer 126 that overlies the first portions 38′ of the low acoustic impedance regions 38, so as to form second temporary trenches T₂ that extend through the first conductive layer 126 and are delimited at bottom by the first portions 38′ of the low acoustic impedance regions 38. The second temporary trenches T₂ are laterally staggered with respect to the first temporary trenches T₁. Furthermore, the remaining portions of the first conductive layer 126 form a corresponding high acoustic impedance layer 26 of the central acoustic mirror 25 and first portions 36′ of the high acoustic impedance regions 36 of the peripheral acoustic mirrors 30. In particular, the first portions 36′ of the high acoustic impedance regions 36 are formed by the portions of the first conductive layer 126 that extend inside and above the first temporary trenches T₁. Each second temporary trenches T₂ is delimited laterally by a corresponding pair of first portions 36′ of the high acoustic impedance regions 36 or by the abovementioned corresponding high acoustic impedance layer 26 and a corresponding first portion 36′ of the high acoustic impedance regions 36.

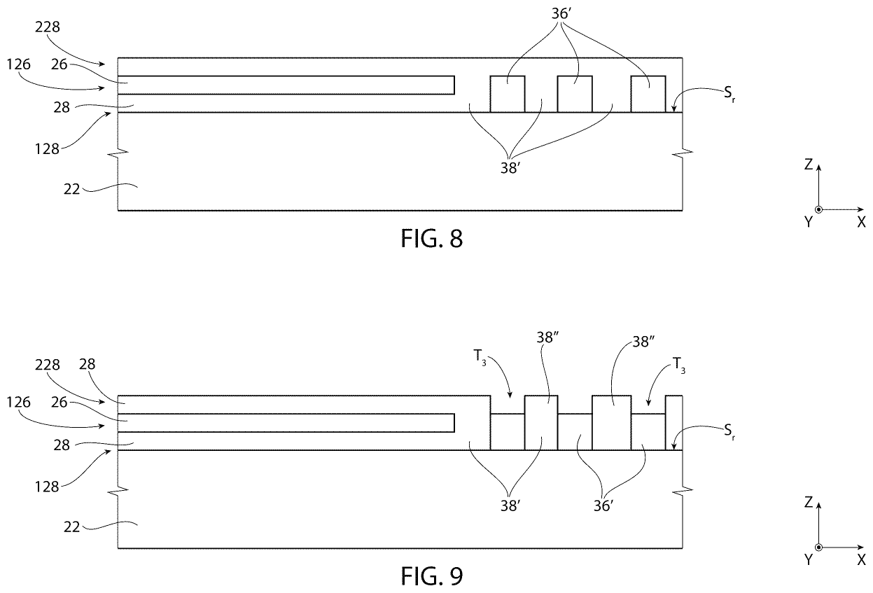

Afterwards, as shown in FIG. 8, a second dielectric layer 228 made of silicon oxide is formed on the first conductive layer 126, namely on the corresponding high acoustic impedance layer 26, on the first portion 36′ of the high acoustic impedance regions 36 and in the second temporary trenches T₂, so as to fill the second temporary trenches T₂.

Subsequently, as shown in FIG. 9, a dry etching is carried out, in order to selectively remove portions of the second dielectric layer 228 that overlies the first portions 36′ of the high acoustic impedance regions 36, so as to form third temporary trenches T₃ that extend through the second dielectric layer 228 and are delimited at bottom by the first portions 36′ of the high acoustic impedance regions 36. To a first approximation, the third temporary trenches T₃ are respectively vertically aligned to the first temporary trenches T₁. Furthermore, the remaining portions of the second dielectric layer 228 form a corresponding low acoustic impedance layer 28 of the central acoustic mirror 25 and second portions 38″ of the low acoustic impedance regions 38 of the peripheral acoustic mirrors 30, which extend inside and above the second temporary trenches T₂ and lie, respectively, on corresponding first portions 38′ of the low acoustic impedance regions 38 of the peripheral acoustic mirrors 30.

Then, the manufacturing process may continue by iterating the same operations as the ones described with reference to FIGS. 6-9.

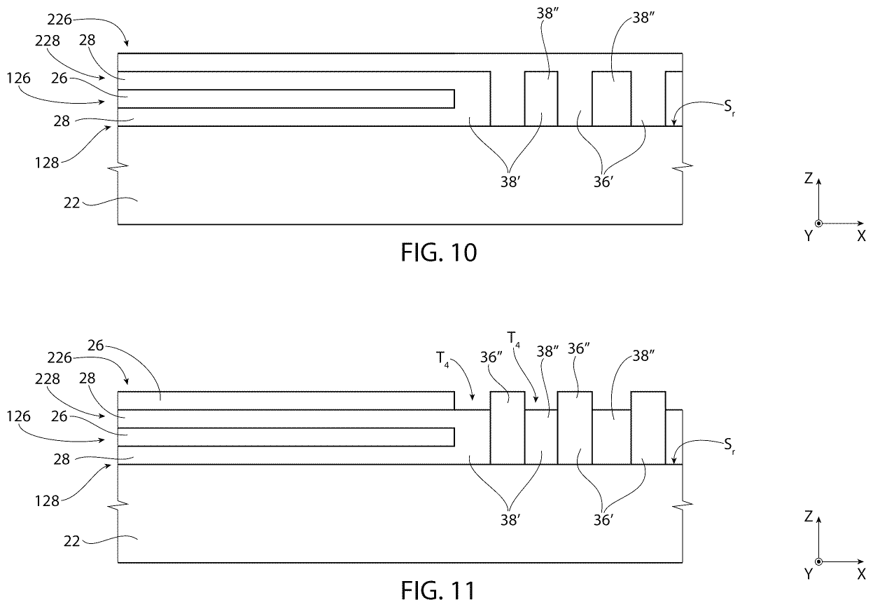

In detail, as shown in FIG. 10, a second conductive layer 226 made of the same conductive material as the first conductive layer 126 is formed on the second dielectric layer 228, namely on the currently exposed low acoustic impedance layer 28 of the central acoustic mirror 25, on the second portions 38″ of the low acoustic impedance regions 38 of the peripheral acoustic mirrors 30 and inside the third temporary trenches T₃, so as to fill the third temporary trenches T₃.

Subsequently, as shown in FIG. 11, a dry etching is carried out, in order to selectively remove portions of the second conductive layer 226 that overlie the second portions 38″ of the low acoustic impedance regions 38, so as to form fourth temporary trenches T₄ that extend through the second conductive layer 226 and are delimited at bottom by the second portions 38″ of the low acoustic impedance regions 38. To a first approximation, the fourth temporary trenches T₄ are respectively vertically aligned with the second temporary trenches T₂. Furthermore, the remaining portions of the second conductive layer 226 form a corresponding high acoustic impedance layer 26 of the central acoustic mirror 25 and second portions 36″ of the high acoustic impedance regions 36 of the peripheral acoustic mirrors 30; in particular, the second portions 36″ of the high acoustic impedance regions 36 are formed by the portions of the second conductive layer 226 that extend inside and above the third temporary trenches T₃ and lie, respectively, on corresponding first portions 36′ of the high acoustic impedance regions 36 of the peripheral acoustic mirrors 30. Each first portion 36′ and the corresponding second portion 36″ form a corresponding high acoustic impedance region 36.

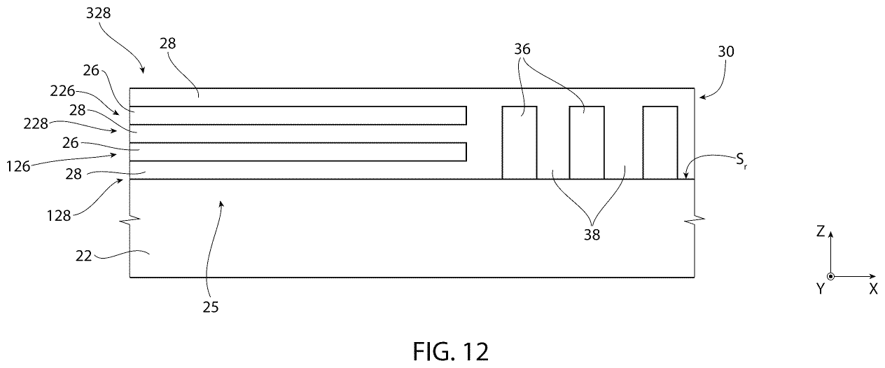

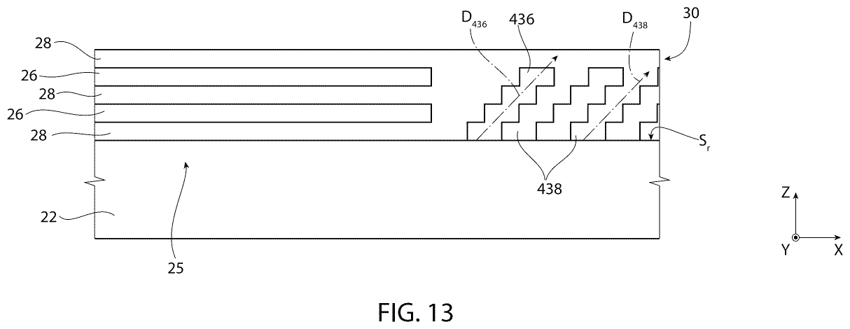

Afterwards, as shown in FIG. 12, a third dielectric layer 328 made of silicon oxide is formed on the remaining portions of the second conductive layer 226, so as to fill the fourth temporary trenches T₄. In this way, the formation of the central acoustic mirror 25 and the peripheral acoustic mirrors 30 is completed.

Then, though not shown, the manufacturing process may continue in a per se known manner, so as to form the piezoelectric resonator 50.

Basically, the manufacturing process comprises iterating a number of times the steps of: forming a layer made of a first material and patterning the layer made of the first material by etching corresponding trenches, so as to form a corresponding layer of the central acoustic mirror 25 and corresponding portions of regions of a first type of the peripheral acoustic mirrors 30; on the layer made of the first material, forming a layer made of a second material, so that portions of the layer made of the second material extend in the trenches through the layer made of the first material; patterning the layer made of the second material by etching corresponding trenches that are laterally staggered with respect to the trenches previously etched through the layer made of the first material and are delimited at bottom by corresponding portions of regions of the first type of the peripheral acoustic mirrors 30, so that the remaining portions of the layer made of the second material form a corresponding layer of the central acoustic mirror 25 and corresponding portions of regions of a second type of the peripheral acoustic mirrors 30, these latter regions being formed in particular by the portions the layer made of the second material that extend in the trenches previously etched through the layer made of the first material.

The advantages that the present resonator device affords are clear from the preceding description. In particular, owing to the presence of the peripheral acoustic mirrors, in a frequency band including the resonance frequency of the resonator device, the portions of the resonator device that surround the piezoelectric resonator support evanescent waves only; in such a way, the spurious modes are suppressed (i.e., they are moved out of the abovementioned frequency band), thereby limiting the lateral acoustic dispersion and improving the energy confinement. Therefore, the resonator device has an improved quality factor.

Finally, it is clear that modifications and variations may be made to the resonator device previously described, without departing from the scope of the present invention, as defined in the attached claims.

For example, though not shown, an intermediate layer made of, e.g., aluminum nitride may be interposed between the topmost layer of the central acoustic mirror and the bottom electrode, in particular in case the topmost layer of the central acoustic mirror is made of a conductive material.

In addition, the shapes, the number, the widths and the arrangements of the regions of the peripheral acoustic mirrors may differ with respect to the ones previously described. The same applies to the layers of the central acoustic mirror. Purely as an example, the topmost layer and/or the bottommost layer of the central acoustic mirror may be formed by high acoustic impedance layers, instead of low acoustic impedance layers.

As an example, though not shown, embodiments are possible, in which the central acoustic mirror is completely surrounded, laterally, by the peripheral acoustic mirrors.

Furthermore, embodiments are possible that include only one peripheral acoustic mirror, which laterally surrounds at least part of the central acoustic mirror; furthermore, the peripheral acoustic mirror may have, to a first approximation, a circular symmetry, i.e. the low and high acoustic impedance regions may have the shapes, in top plan view, of concentric portions of annuluses.

As a further example, FIG. 13 shows a variant, in which the high and low acoustic impedance regions (here designated by 436 and 438) have ladder profiles, which extend along corresponding directions D₄₃₆ and, respectively, D₄₃₈, and have steps which are approximately parallel to the plane XY.

In greater detail, FIG. 13 shows a peripheral acoustic mirror 30 and may refer to a cross-section taken in a plane parallel to the sequence direction of the peripheral acoustic mirror 30 and perpendicular to the plane XY. Furthermore, the directions D₄₃₆ and D₄₃₈ represent elongation directions of the shapes of the high acoustic impedance regions 436 and, respectively, the low acoustic impedance regions 438. In addition, the directions D₄₃₆ and D₄₃₈ may be parallel and are tilted, with respect to the pane XY, by a corresponding angle, which is greater than zero and lower than 90°. Furthermore, though not shown in FIG. 13, the width of the steps of the ladder profile of each of the high and low acoustic impedance regions 436, 438 may vary along the respective direction D₄₃₆, D₄₃₈.

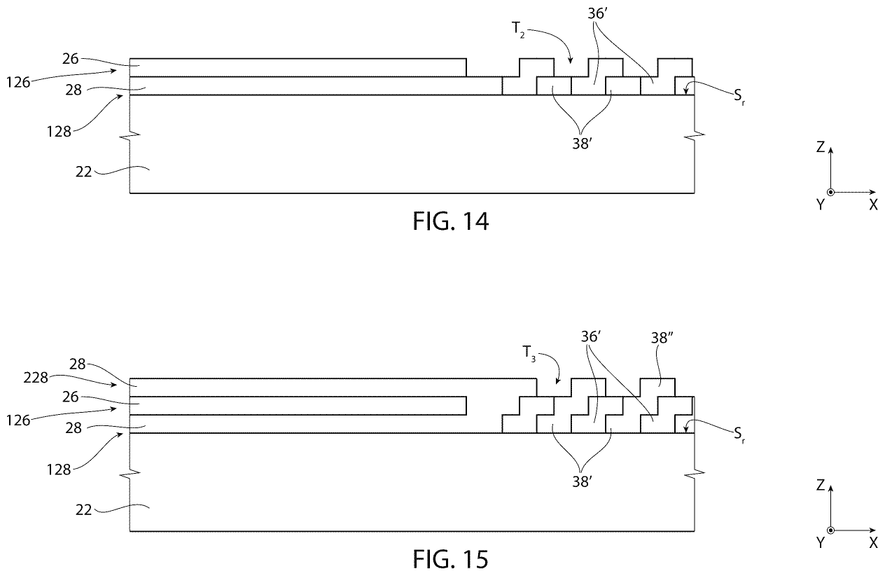

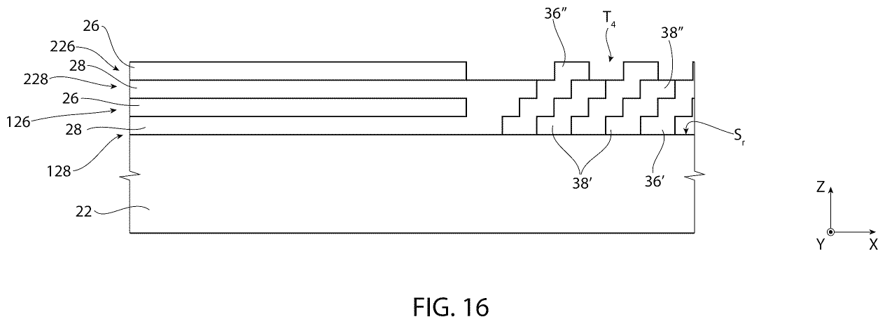

The variant shown in FIG. 13 may be formed by the same process described with reference to FIGS. 4-12, by laterally staggering the second temporary trenches T₂ with respect to the first portions 38′ of the low acoustic impedance regions 38, so that each second temporary trench T₂ is delimited at bottom by a part of a corresponding first portion 38′ and by a part of a corresponding first portion 36′ of the high acoustic impedance regions 36, as shown in FIG. 14. In this case, each first portion 36′ has the shape of a two-step ladder, thus includes a respective lower part, which delimits at bottom the corresponding second temporary trench T₂, and a respective upper part, which laterally delimits the corresponding second temporary trench T₂. Furthermore, as shown in FIG. 15, also the second portions 38″ have the shape of a two-step ladder and thus have, each, a corresponding upper part and a corresponding lower part; in addition, the third temporary trenches T₃ are laterally staggered so that each third temporary trench T₃ is delimited at bottom by a part of the upper part of a corresponding first portion 36′ and by a part of a lower part of a corresponding second portion 38″. Furthermore, as shown in FIG. 16, also the second portions 36″ have the shape of a two-step ladder, and the fourth temporary trenches T₄ are laterally staggered so that each fourth temporary trench T₄ is delimited at bottom by a part of the upper part of a corresponding second portion 38″ and by a part of the lower part of a corresponding second portion 36″.

Finally, the shapes of the top and bottom electrodes and of the piezoelectric region may differ with respect to the previous description. As an example, though not shown, the bottom electrode and the piezoelectric region of the piezoelectric resonator may have a reduced lateral extension, as an example so as to leave exposed portions of the peripheral acoustic mirrors or the whole peripheral acoustic mirrors.

1. A bulk acoustic wave resonator device, comprising:
a piezoelectric resonator comprising a top electrode, a bottom electrode and a piezoelectric region interposed between the top electrode and the bottom electrode;
a central acoustic mirror of Bragg type arranged under the piezoelectric resonator and including respective layers extending parallel to a reference plane; and
one or more peripheral acoustic mirrors of Bragg type arranged laterally with respect to the central acoustic mirror;
wherein each peripheral acoustic mirror comprises a respective sequence of alternating high acoustic impedance regions and low acoustic impedance regions, each high acoustic impedance region and each low acoustic impedance region extending transversally with respect to the reference plane.

2. The resonator device according to claim 1, wherein each high acoustic impedance region and each low acoustic impedance region of each peripheral acoustic mirror extend parallel to a vertical direction, which is perpendicular to the reference plane.

3. The resonator device according to claim 1, wherein each peripheral acoustic mirror laterally surrounds, at least in part, the central acoustic mirror.

4. The resonator device according to claim 1, further comprising a semiconductive body; and wherein the central acoustic mirror and the one or more peripheral acoustic mirrors are arranged above the semiconductive body; and wherein each high acoustic impedance region and each low acoustic impedance region of each peripheral acoustic mirror extend from a top surface of the semiconductive body.

5. The resonator device according to claim 1, wherein each high acoustic impedance region and each low acoustic impedance region has a shape that is elongated in at least one corresponding elongation direction, said elongation direction being transversal with respect to the reference plane.

6. The resonator device according to claim 1, wherein the central acoustic mirror comprises a respective sequence of alternating and vertically stacked high acoustic impedance layers and low acoustic impedance layers.

7. The resonator device according to claim 6, wherein the high acoustic impedance layers and the high acoustic impedance regions are made of a same material; and wherein the low acoustic impedance layers and the low acoustic impedance regions are made of a same material.

8. A resonator device according to claim 1, said resonator device being of the solidly-mounted type.

9. A process for manufacturing a bulk acoustic wave resonator device, comprising:
forming a piezoelectric resonator including a top electrode, a bottom electrode and a piezoelectric region interposed between the top electrode and the bottom electrode;
forming a central acoustic mirror of Bragg type arranged under the piezoelectric resonator and including respective layers extending parallel to a reference plane; and
forming one or more peripheral acoustic mirrors of Bragg type arranged laterally with respect to the central acoustic mirror;
wherein forming each peripheral acoustic mirror comprises forming a respective sequence of alternating high acoustic impedance regions and low acoustic impedance regions, each high acoustic impedance region and each low acoustic impedance region extending transversally with respect to the reference plane.

10. The manufacturing process according to claim 9, comprising iterating a number of times:
forming a first layer made of a first material and then forming trenches through the first layer, so that remaining portions of the first layer form a corresponding layer of the central acoustic mirror and corresponding portions of regions of a first acoustic type of the peripheral acoustic mirrors;
on the first layer, forming a second layer made of a second material, so that portions of the second layer extend in the trenches through the first layer;
then forming trenches through the second layer, said trenches through the second layer being laterally staggered with respect to the trenches through the first layer, so that remaining portions of the second layer form a corresponding layer of the central acoustic mirror and corresponding portions of regions of a second acoustic type of the peripheral acoustic mirrors.

11. A bulk acoustic wave resonator device, comprising:
a support substrate;
a central acoustic mirror of Bragg type arranged over the support substrate and including a stack of alternating high acoustic impedance layers and low acoustic impedance layers extending parallel to an upper surface of the support substrate;
a peripheral acoustic mirror of Bragg type arranged laterally with respect to the central acoustic mirror and including a sequence of alternating high acoustic impedance regions and low acoustic impedance regions extending transversally with respect to the upper surface of the support substrate; and
a piezoelectric resonator comprising a top electrode, a bottom electrode and a piezoelectric region extending over at least the central acoustic mirror.

12. The resonator device according to claim 11, wherein at least one acoustic impedance layer and at least on low acoustic impedance layer in the stack extend over the peripheral acoustic mirror.

13. The resonator device according to claim 11, wherein the top electrode of the piezoelectric resonator extends over the central acoustic mirror but does not extend over the peripheral acoustic mirror.

14. The resonator device according to claim 13, wherein the bottom electrode of the piezoelectric resonator extends over both the central acoustic mirror and the peripheral acoustic mirror.

15. The resonator device according to claim 11, wherein the sequence of alternating high acoustic impedance regions and low acoustic impedance regions for the peripheral acoustic mirror are arranged to substantially surround the of alternating high acoustic impedance layers and low acoustic impedance layers for the central acoustic mirror.
